(19) United States
(12) Patent Application Publication
(10) Pub. No.: US 2005/0230627 A1
(43) Pub. Date: Oct. 20, 2005

(54) Position-sensitive germanium detectors having a microstructure on both contact surfaces

(75) Inventors: Davor Protic, Julich (DE); Thomas Krings, Linnich (DE)

Correspondence Address: FOLEY AND LARDNER;SUITE 500, 3000 K STREET NW, WASHINGTON, DC, 20007, US

(73) Assignee: FORSCHUNGSZENTRUM JULICH GmbH, Julich (DE)

(21) Appl. No.: 10/511,734

(22) PCT Filed: Apr. 3, 2003
(86) PCT No.: PCT/EP03/03485

§ 371 Date: Oct. 18, 2004

(30) Foreign Application Priority Data
Apr. 18, 2002 (DE) 102 17 426.1

(51) Int. Cl. H01L 31/115

(52) U.S. Cl. 250/370.01

(57) ABSTRACT

The invention relates to a position-sensitive detector for measuring charged particles comprising a surface region, which is formed by an amorphous layer with a structured metallic layer disposed above it, characterised in that the structure of the metallic layer is continued into the amorphous layer.

The invention discloses a position-sensitive detector for measuring charged particles or photons. Moreover, the invention relates to a tomograph or Compton camera with a detector of this kind.

A detector of the kind named above is already known from the document “High Purity Germanium Position-Sensitive Detector for Positron Annihilation Experiments”, G. Riepe, D. Protlic, R. Kurz, W. Triftshauser, Zs. Kajcsos and J. Winter, Proceedings 5^{th} International Conference on Positron Annihilation, (Japan, 1979). This document describes a detector consisting of very pure crystalline germanium provided with microstructures on both sides. Phosphorus is implanted on one side of the detector and boron is implanted on the other side. The implantation is carried out by ion implantation.

If a charged particle or photon strikes the detector, it produces pairs of electron-holes in the region of the crystalline germanium. The relevant charge migrates to the corresponding contact, where it is read out. The position-dependent charge measured presents a measure for the required information.

Boron-doped contacts, in particular, can be manufactured very simply by ion implantation.

In principle, implantation with phosphorus is also a technically very simple method. However, the occurrence of radiation damage, which can lead to p⁺-doping in a layer, which is actually supposed to represent an n− or n⁺ layer, is disadvantageous. Radiation damage therefore has a disturbing effect.

Attempts to temper a detector have been made in order to solve the problem of radiation damage. This tempering is carried out at temperatures of typically 350 to 400° C. The tempering stage minimises radiation damage, so that, after successful implementation, a good n− or n⁺ contact is achieved in the relevant layer.

It is disadvantageous that a crystal on the surface is often contaminated, especially by the presence of copper. Copper typically diffuses very rapidly into the crystal at the temperatures required for tempering. This frequently leads to such disturbing effects, that the detector as a whole is unusable. The very expensive materials cannot be reused. Because of the very high failure quota, the above manufacturing method is very expensive.

To obtain a position-sensitive detector, the n and/or p layers are provided with structures. The structures can be produced using a lithographic method. Such lithographic methods are already known within the general specialist knowledge. With one photo-photolithographic method, a photo-sensitive paint is applied to the surface, which is to be structured. The photo-sensitive paint is partially exposed through a shadow mask. Using plasma etching, grooves are then introduced into the surface in the exposed parts of the photo-sensitive paint. The n layer and/or p layer is then structured. This should be understood to mean that the layer acting as the n contact or p contact is subdivided into individual segments, which are separated from one another by grooves. These separated elements are frequently referred to in the literature as position elements. Finally, the paint layer may be removed, for example, by chemical etching.

The structuring can be provided on both sides in the form of strips. The strips on the one side are then aligned, for example, perpendicularly relative to the strips on the other side. In principle, however, any required geometric pattern is possible. For instance, a spiral structuring has been provided on both sides. In this instance, the spirals ran in opposite directions, thereby similarly allowing a positional resolution.

Further examples for possible structuring can be found in the document “Nuclear Instruments and Methods in Physics Research”, Section A, A 421 (1991) pages 447-457, M. Betigeri et al.

The known structures can also be provided in the context of the present invention.

In order to avoid the problematic phosphorus layer, attempts have already been made to replace the phosphorus with lithium. However, the disadvantage with lithium is that the fine structures attainable with phosphorus are not possible. The cause for this is that lithium penetrates very deeply into the crystal. Lithographic methods including plasma etching can no longer be used, because the required depth cannot be achieved. It is therefore necessary to structure the lithium layer by sawing. However, this technique does not allow the fine resolution attainable with lithographic methods. Accordingly, with a detector, which is doped with lithium on one side, it is not possible to achieve very great positional resolution.

In view of the thickness of the lithium layer, which is typically 200 to 1000 μm thick, it is also disadvantageous that transmission detectors cannot be provided.

To avoid a phosphorus layer and the associated disadvantages while still achieving good positional resolution, including a transmission detector, attempts have been made to replace the phosphorus layer with an amorphous germanium layer, which is provided with an aluminium surface layer. A prior art of this kind is disclosed, for example, in the document “A 140-Element Germanium Detector Fabricated with Amorphous Germanium Blocking Contacts” P. N. Luke et al., IEEE Transactions Nuclear Science, Vol. 41, No. 4, August 1994.

The aluminium can be replaced with other metals such as palladium or gold.

To achieve the desired structuring with the above-named prior art, the metal is structured by application in strips. With this prior art, the amorphous germanium layer is not structured. This layer is only very slightly conductive, so that the structuring of the metal surface is sufficient to obtain a position-sensitive detector.

However, experiments have shown that in the case of the above-named detector with the structured metallic surface, only a comparatively poor energy resolution can be achieved. Furthermore, a relatively large number of measuring errors occur in the energy measurement.

The object of the present invention is to provide a detector of the type named above with improved accuracy in the energy measurement and improved energy resolution in the measurement.

The object of the invention is achieved by a position-sensitive detector with the features of claim 1. Advantageous embodiments are defined in the dependent claims. A method for manufacturing a detector is specified in the subsidiary claim.

The object of the invention is achieved with a position-sensitive detector for measuring charged particles comprising a surface region, which is formed by an amorphous layer with a structured metallic layer disposed above it. The structure of the metallic layer is continued into the a amorphous layer. According to the invention, it is therefore relevant that not only the metallic surface is structured but also the amorphous layer disposed beneath it. These structures match one another.

The structure of the metallic layer advantageously extends through the amorphous layer into the crystalline structure onto which the amorphous layer is applied.

It has been shown that the measuring accuracy of the energy measurement is increased by comparison with the prior art, if the structuring extends into the amorphous layer. The energy resolution attainable is also significantly improved. These improvements are particularly successful if the structure is continued through the amorphous layer and into the crystalline structure disposed beneath it. A few μm depth of the structure in the crystalline region are sufficient. The structure should extend to a depth of at least 1 μm, preferably at least 5 μm, into the semiconductor region.

Very good results have been achieved with an amorphous layer made of germanium. The metallic layer can consist, for example, of aluminium, palladium or gold. The crystalline region beneath the amorphous layer then preferably also consists of germanium.

To achieve good positional resolution, the structure is formed in segments, which provide a mutual spacing of less than 200 μm, in particular a spacing of less than 100 μm, by particular preference of less than 20 μm. The lower threshold realisable in practice is approximately 1 μm. The desired microstructures may be produced, for example, using a photo-photolithographic method.

The amorphous layer is always applied to a semiconductor material. The amorphous layer therefore provides an electrical conductivity, which is substantially smaller than the conductivity of the material disposed beneath the amorphous layer.

In one exemplary embodiment for the manufacture of the invention, an amorphous germanium layer is initially applied by sputtering or vapour deposition. A metallic layer, for example, an aluminium layer, is subsequently applied by vapour deposition. The desired structures are then produced in a defined manner lithographically. Grooves are etched in the amorphous germanium-metallic layer to such a depth that they extend at least into the germanium crystal region. These grooves advantageously extend into the germanium crystal. The opposing contact (p⁺) has already been produced on the opposite side by doping with boron and subsequent microstructuring.

The following advantages were found in the exemplary embodiment:
an individual readout of segments below 100 μm wide is possible;
a positional resolution of better than 100 μm×100 μm can be realised;
operating at high count rates above 10⁵ events per second is possible;
a rapid position measurement (typically 20 ns for germanium) can be implemented for the purpose of triggering and to resolve ambiguities;
two or more particles or photons occurring simultaneously can be successfully detected;
a three-dimensional position measurement (Δz˜100 μm) can be implemented through individual drift-time measurements for each segment with time resolutions <10 ns FWHM;
particle identification can be implemented by measuring the drift-time differences.

The dimensions of a detector are typically 3 inches in diameter. The thickness of the detector is typically 10 to 20 mm. The effective thickness of the boron layer is typically less than 1 atm. The thickness of the amorphous germanium layer is typically approximately 0.1 μm. The metallic layer is typically 0.1 to 0.2 μm thick. The depth of the grooves is typically 10 μm.

With the prior art, implanted boron generally extends 10 μm or even 20 μm into the germanium crystal. Etching has also been carried out down to this depth. The present invention is distinguished from the prior art in particular in that the depth of the grooves extends very much further than would have been necessary for the metallic layer, or indeed for the amorphous germanium layer, in itself. This is essential to the invention in order to achieve the optimum effect.

A crystal made from silicon may be provided instead of a germanium crystal.

The detector is used especially in the field of medicine, because the previously used detectors do not provide the necessary positional resolutions at the same time as providing high count rates. With the present invention, the positional resolution can be increased practically without limitation. In terms of scale, the positional resolution can be doubled, by comparison with detectors previously used in medicine, without difficulty and without detriment to the other performance capabilities. The positional resolution attainable in medical applications was previously 2 mm. Positional resolutions of 1 mm can now be realised without difficulty. In the field of tomography in particular, the detector can be used to achieve substantially improved results.

Positron emission tomography represents another medical field, in which the detector can advantageously be used. SPECT is another exemplary application. In this case, the detector represents a special component of a Compton camera. Small-animal positron emission tomography is another typical exemplary application in the field of medicine.

Another important area of application for the present detector is in astrophysics.

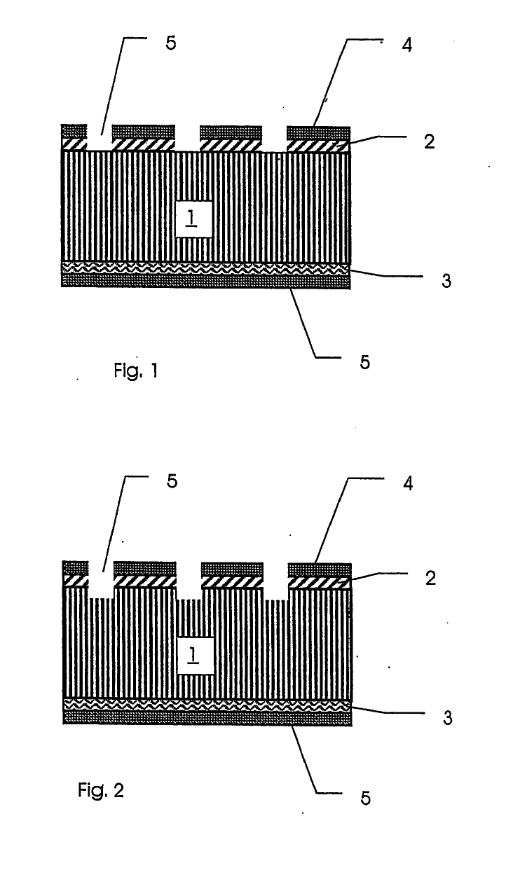

Exemplary embodiments of the invention will be explained in greater detail below with reference to FIGS. 1 and 2.

FIG. 1 shows a section through a semiconductor 1 consisting of germanium. On one surface, the semiconductor 1 provides a layer 2, which consists of amorphous germanium. This forms an n⁺ contact. A layer 3 of the semiconductor, which is doped with boron, is disposed opposite to this. This provides a p⁺ contact. Metallic layers 4 and 5 are applied to the layers 2 and 3, for the purpose of electrical contact.

By way of distinction from the prior art, not only the metallic layer on the side with the n⁺ contact is structured in strips. Instead, the grooves 5 extend down into the amorphous layer 2, so that this layer provides segments individually separated from one another.

On the opposite side, the p⁺ contact can also be structured in strips. In this case, the strips always run perpendicular to the strips on the side with the amorphous germanium (that is to say, parallel to the plane of the paper). For this reason no grooves are visible.

A particularly good performance can be achieved with the embodiment according to FIG. 2. In this case, the grooves 5 extend down into the semiconductor material.

Crystalline and/or amorphous silicon, for example, may be used instead of germanium. As the semiconductor material, III-V compounds such as GaAs or CdTe may be considered. It was found that the layer 3 can be replaced by amorphous germanium or by amorphous silicon instead of doping with boron. The method of functioning in this case has not be explained in physical terms.

The width of the grooves is between 1 and 200 μm. The strips are therefore at a distance of 1 to 200 μm from one another.

1. Position-sensitive detector for measuring charged particles comprising a surface region, which is formed by an amorphous layer with a structured, metallic layer disposed above it,
characterised in that
the structure of the metallic layer is continued into the amorphous layer.

2. Position-sensitive detector according to claim 1, characterised in that the structure of the metallic layer extends through the amorphous layer into the crystalline structure, onto which the amorphous layer is applied.

3. Position-sensitive detector according to claim 1, characterised in that the amorphous layer is formed from germanium or silicon.

4. Position-sensitive detector according to claim 1, characterised in that the metallic layer consists of aluminium, palladium or gold.

5. Position-sensitive detector according to claim 1, characterised in that the crystalline region beneath the amorphous layer is formed of germanium, silicon or a III-V compound.

6. Position-sensitive detector according to claim 1, characterized in that the structure is formed from segments, which provide a mutual spacing of less than 200 μm, in particular, a spacing of less than 100 μm, by particular preference less than 20 μm.

7. Position-sensitive detector according to claim 1, characterised in that the amorphous layer is applied to a semiconductor material.

8. Position-sensitive detector according to claim 1, characterised in that the amorphous layer provides an electrical conductivity, which is substantially less than the conductivity of the material disposed beneath the amorphous layer.

9. Tomograph or Compton camera with a detector according to claim 1.
